(19) United States
(12) Patent Application Publication
(10) Pub. No.: US 2007/0234158 A1
(43) Pub. Date: Oct. 4, 2007

(54) METHOD OF TESTING A SEMICONDUCTOR MEMORY DEVICE, METHOD OF DATA SERIALIZATION AND DATA SERIALIZER

(75) Inventor: Sang-Woong SHIN, Gyeonggi-do (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (KR)

(21) Appl. No.: 11/679,809

(22) Filed: Feb. 27, 2007

(30) Foreign Application Priority Data
Feb. 28, 2006 (KR) 2006-0019177

(51) Int. Cl. G01R 31/28

(52) U.S. Cl. 714/731

(57) ABSTRACT

A semiconductor memory device is tested responsive to an output clock signal. Parallel test data in the semiconductor memory device are generated and a plurality of data output clock signals are generated by selectively activating one of the data output clock signals according to a test mode. The parallel test data are respectively applied to a plurality of output circuits and one of the output circuits is activated responsive to the activated data output clock signal. The parallel test data transferred through the activated output circuit are serialized and the serialized data are output responsive to the output clock signal. Therefore, the semiconductor memory device is tested without loss of a valid data output time.

### CROSS-REFERENCE TO RELATED APPLICATIONS

This application claims priority under 35 USC § 119 to Korean Patent Application No. 10-2006-0019177, filed on Feb. 28, 2006, in the Korean Intellectual Property Office (KIPO), the disclosure of which is incorporated herein in its entirety by reference.

### BACKGROUND OF THE INVENTION

1. Field of the Invention

The present invention relates to a method and system of testing a semiconductor memory device. More particularly, the present invention relates to a method and system of testing a semiconductor memory device in a high-speed data output test mode. The present invention also relates to a method of data serialization using a data serializer.

2. Description of the Related Art

The operating speeds of semiconductor memory devices have gradually increased over time. But the operating speeds of testers for the semiconductor memory devices have not kept pace with the ever-increasing operating speeds of the memory devices themselves. Accordingly, a method of testing a relatively high-speed memory device using a relatively low-speed tester has been proposed. One of the proposed methods includes operating a memory device faster than the clock speed of the tester by multiplying an external memory clock signal. The tester may provide the multiplier which, may also be part of the memory device. The external memory clock signal can be multiplied by performing an XOR operation, by using a phase-locked loop (PLL), or both. This test mode is referred to as a clock doubling test mode.

FIG. 1 shows a timing diagram including noises in output data according to a conventional clock doubling test.

FIG. 1 illustrates noises that can be caused when a clock doubling test mode is applied to a synchronous dynamic random-access memory (SDRAM) device—specifically, an SDRAM device which has implemented a double data rate (DDR). Output test data, indicated by DATA of FIG. 1, are output at every edge of the clock signal. A core of the memory device may generate a large amount of noise in a particular test pattern. In this case, the power supply voltage and/or the ground voltage may be varied due to the noise. The phase of the clock signal generated from a PLL and/or a delay-locked loop (DLL) is varied when the power supply voltage is varied. As a result, as shown in FIG. 1, the phase of the test data output signal is varied and the valid data window (tDV) of the output test data DATA is decreased.

When the phase of the clock signal generated from the DLL and the like is varied, the phase of a data signal and the phase of an output strobe signal are varied together. Accordingly, a system outputting the data signal responsive to the data strobe signal DQS may not be influenced by the phase change in a normal operation mode. However, during the clock doubling test, an external tester may monitor the timing of the data output signal and may detect that an overkill problem has occurred. That is, what was once considered a normal semiconductor memory device (perhaps rightly so) may now be deemed a defective semiconductor memory device because of a decreased valid data window (tDV).

To solve the above problem, the test pattern can be divided into a test pattern for even data and a test pattern for odd data. The even data and the odd data may be output separately. In this manner, the valid data window (tDV) during the test can be increased to substantially twice its previous size. As a result, an overkill problem during the clock doubling test can be reduced. This technique is referred as a high-speed data output (HSDO) test.

In the HSDO test, the output of the odd data is blocked when the even data is output and the output of the even data is blocked when the odd data is output. This allows the even data and the odd data to have twice the valid data window in a data serializer.

FIG. 2 shows a circuit diagram including a conventional data serializer.

Referring to FIG. 2, in a data serializer 20, an output circuit 21 outputs data at a rising edge and an output circuit 22 outputs data at a falling edge, each of which are coupled to an output latch 23. The output circuit 21 includes two transmission gates 211 and 213, and a latch 212 coupled serially between the transmission gates 211 and 213. The output circuit 21 further includes a switch 214 for selectively outputting even data DATA_EVEN and odd data DATA_ODD in an HSDO test mode. The output circuit 22 includes two transmission gates 221 and 223, and a latch 222 coupled serially between the transmission gates 221 and 223. In addition, the output circuit 22 further includes a switch 224 for selectively outputting the even data DATA_EVEN and the odd data DATA_ODD.

The transmission gates 211, 213, 221 and 223 are turned on/off responsive to an output clock signal CLKDQ. When the output clock signal CLKDQ is logic high, the even data DATA_EVEN stored in the latch 212 in the even data output circuit 21 is transmitted to the output latch 23, and the odd data DATA_ODD is stored in the latch 222 in the odd data output circuit 22. When the CLKDQ is logic low, the odd data DATA_ODD stored in the latch 222 in the odd data output circuit 22 is transmitted to the output latch 23, and the even data DATA_EVEN is stored in the latch 212 in the even data output circuit 21.

Switches 214 and 224 may be implemented by first inverters 215 and 225 (otherwise known as tristate inverters) operating according to test signals TEST_EVEN and TEST_ODD, respectively. The second inverters 216 and 226 operate by inverting the data output signal back again.

During an even data test mode, the even test signal TEST_EVEN becomes logic high, and the data serializer 20 outputs the even data DATA_EVEN and blocks the odd data DATA_ODD. While the even data test mode is maintained, the data serializer continues to output the even data DATA_EVEN.

During an odd data test mode, the odd test signal TEST_ODD becomes logic high, and the data serializer 20 outputs the odd data DATA_ODD and blocks the even data DATA_EVEN. While the odd data test mode is maintained, the data serializer continues to output the odd data DATA_ODD.

Despite the benefits of separating the even data test mode from the odd data test mode, additional gates—such as the gates included in switches 214 and 224—lengthen the output circuit of a high-speed memory device and can delay the output signal. As a result, a valid data output time (tAA) elapsed from the reception of an output command is increased, and a valid data window (tDV) is decreased, As a result, the performance of a semiconductor memory device is degraded during a normal operation mode, as well as during a test mode.

### SUMMARY OF THE INVENTION

Accordingly, example embodiments of the present invention are provided to substantially obviate one or more problems due to limitations and disadvantages of the related art.

Some example embodiments of the present invention provide a method of testing a semiconductor memory device responsive to an output clock signal without loss of valid data output time.

Some example embodiments of the present invention provide a method of data serialization without loss of valid data output time.

Some example embodiments of the present invention provide a data serializer capable of preventing loss of valid data output time during a test of a semiconductor memory device.

In one example embodiment of the present invention, a method of testing a semiconductor memory comprises generating test data in the semiconductor memory device, generating a plurality of data output clock signals, controlling a plurality of output circuits with the data output clock signals, selectively activating one of the data output clock signals according to a test mode, selectively deactivating another one of the data output clock signals according to the test mode, activating one of the output circuits responsive to the activated data output clock signal, and serializing the test data transferred through the activated output circuit.

In another example embodiment of the present invention, a method of data serialization, comprises generating a plurality of data output clock signals, controlling a plurality of output circuits with the data output clock signals, selectively activating at least one of the data output clock signals according to an output mode, applying data to at least one of the plurality of output circuits, selectively activating the output circuits responsive to the data output clock signals and the output mode, serializing the data transferred through the at least one activated output circuit; and applying the serialized data to an output latch responsive to the at least one of the activated output clock signals.

In yet another example embodiment of the present invention, a data serializer comprises a clock circuit configured to generate a plurality of data output clock signals, each of the data output clock signals being selectively activated according to an output mode, a plurality of output circuits configured to receive data responsive to at least one of the data output clock signals, and an output latch coupled to the plurality of output circuits, configured to latch data on an output terminal of at least one of the plurality of output circuits responsive to the at least one of the data output clock signals.

Accordingly, the semiconductor memory device may be tested without loss of a valid data output time. The foregoing and other features, objects, and advantages of the various example embodiments of the invention will become more readily apparent from the following detailed description, which proceeds with reference to the accompanying drawings.

### BRIEF DESCRIPTION OF THE DRAWINGS

FIG. 1 shows a timing diagram including noises in output data according to a conventional clock doubling test.

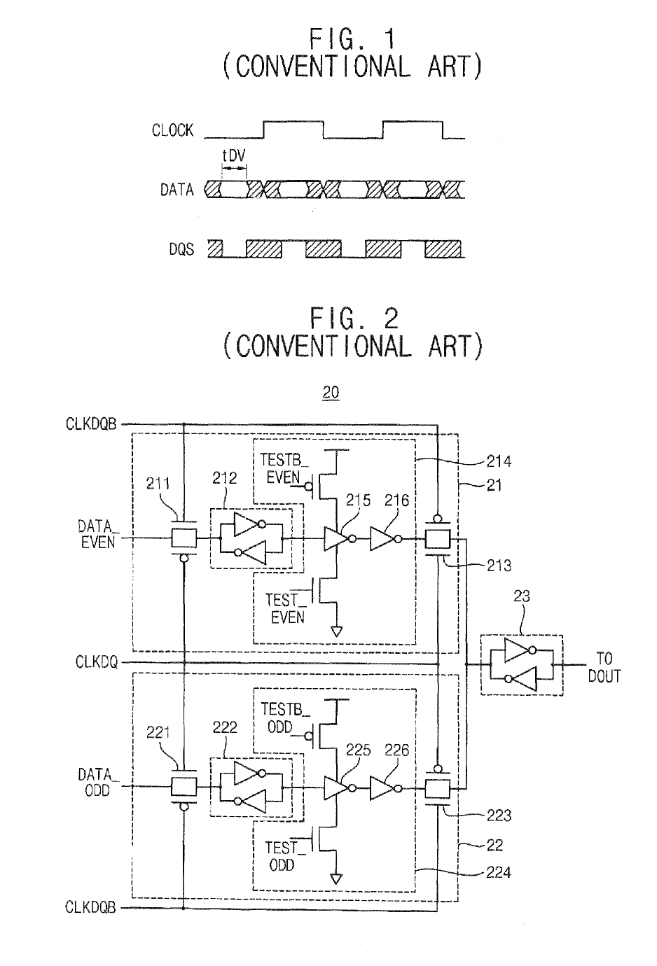

FIG. 2 shows a circuit diagram including a conventional data serializer.

FIG. 3 shows a circuit diagram including a data serializer according to an example embodiment of the present invention.

FIGS. 4 and 5 show timing diagrams including output clock signals provided to the data serializer of FIG. 3, and also show data output from the data serializer.

FIG. 6 shows a circuit diagram including the output clock signal generating circuit of FIG. 3.

FIGS. 7 and 8 show timing diagrams including signals of a data serializer according to an example embodiment operating in an even data test mode and in an odd data test mode.

FIG. 9 shows a timing diagram including signals of a data serializer according to an example embodiment operating in a normal operation mode.

### DESCRIPTION OF THE EMBODIMENTS

Embodiments of the present invention now will be described more fully with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout this application.

It will be understood that, although the terms first, second, etc. may be used herein to describe various elements, these elements should not be limited by these terms. These terms are used to distinguish one element from another. For example, a first element could be termed a second element, and, similarly, a second element could be termed a first element, without departing from the scope of the present invention. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments and is not intended to be limiting of the invention. As used herein, the singular forms “a,” “an”, and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

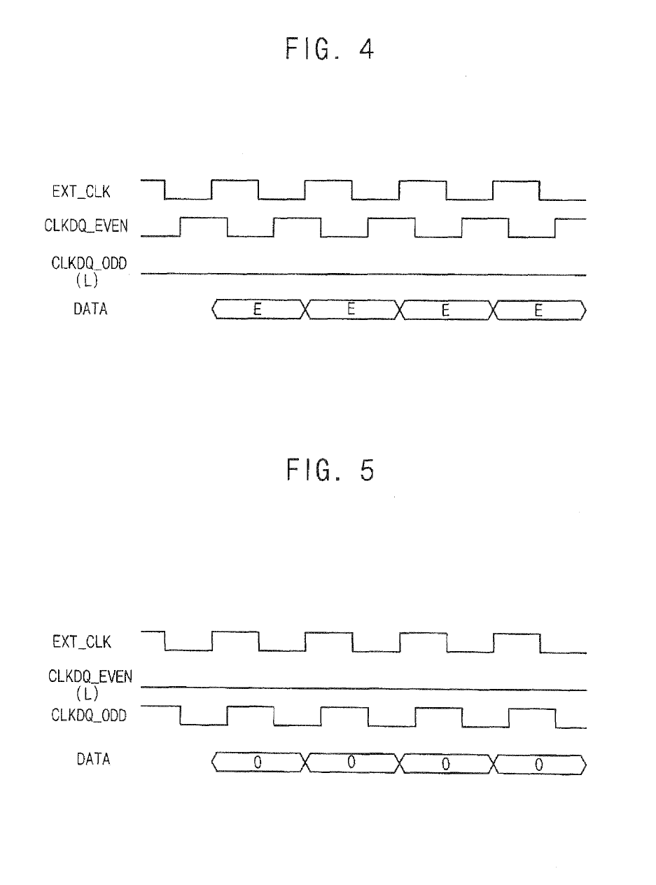

FIG. 3 shows a circuit diagram including a data serializer according to an example embodiment of the present invention.

Although FIG. 3 illustrates serializing and outputting data by receiving two data inputs in one cycle, other embodiments of the present invention may be applied to the method of serializing and outputting data by receiving four, eight or more inputs in one cycle.

Referring to FIG. 3, a data serializer 30 includes an even data output circuit 31, an odd data output circuit 32, an output latch 33, and an output clock signal generating circuit 34. The even data output circuit 31 outputs even data, indicated by DATA_EVEN of FIG. 3, and the odd data output circuit 32 outputs odd data, indicated by DATA_ODD of FIG. 3. The output latch 33 is coupled to both of the output circuits 31 and 32.

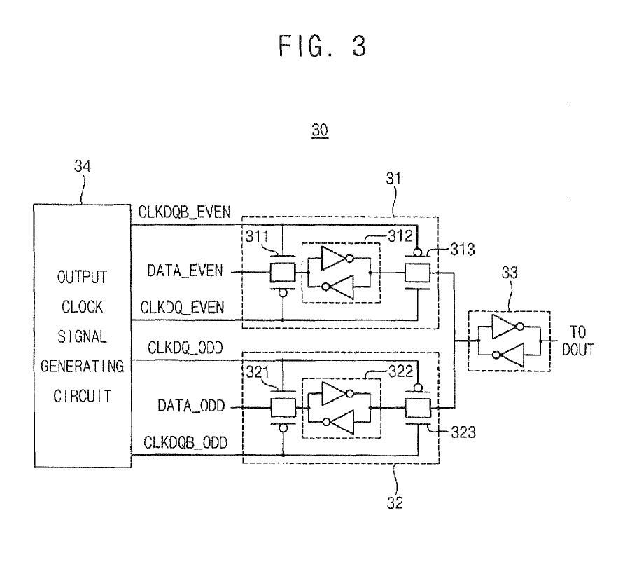

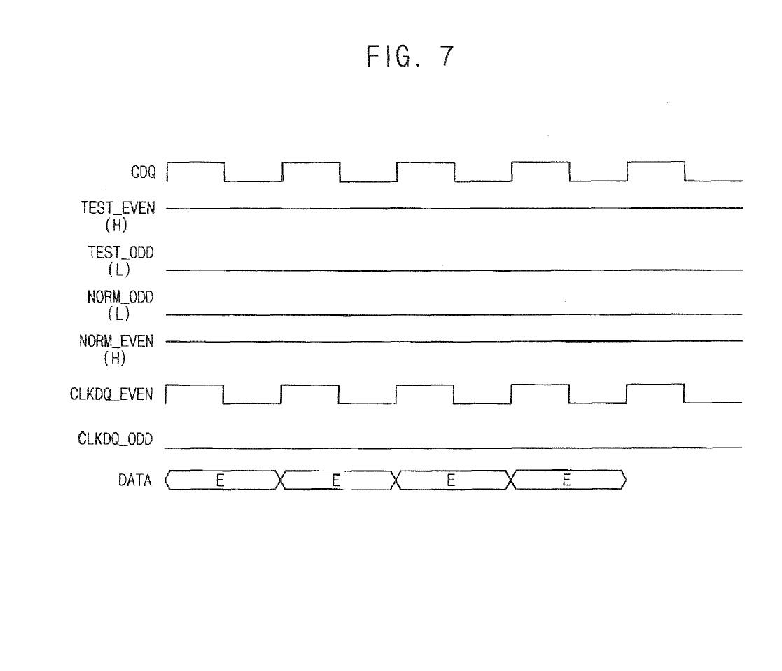

The output circuit 31 includes two transmission gates 311 and 313, and a latch 312 coupled serially between the transmission gates 311 and 313. The output circuit 32 includes two transmission gates 321 and 323, and a latch 322 coupled serially between the transmission gates 321 and 323. Unlike the data serializer 20 in FIG. 2, each of the output circuits 31 and 32 in the data serializer 30 includes fewer gates along the output circuit. For example, the data serializer 20 does not include a switch—such as the switches 214 and 224 of FIG. 2—to selectively output one of even data and odd data. Each of the output circuits 31 and 32 is alternately coupled to the output latch 33 by clock signals CLKDQ_EVEN, CLKDQB_EVEN, CLKDQ_ODD and CLKDQB_ODD, which are provided from the output clock signal generating circuit 34. The clock signals CLKDQ_EVEN, CLKDQB_EVEN, CLKDQ_ODD and CLKDQB_ODD are configured to turn on/off the transmission gates 311, 313, 321 and 323. The output clock signal generating circuit 34 will be described in detail with reference to FIG. 6.

The output circuits 31 and 32 of the data serializer 30 respectively output the even data DATA_EVEN and the odd data DATA_ODD according to an even data output clock signal CLKDQ_EVEN and an odd data output clock signal CLKDQ_ODD. That is, the even data output clock signals CLKDQ_EVEN and CLKDQB_EVEN, and the odd data output clock signals CLKDQ_ODD and CLKDQB_ODD, which are different from each other, are respectively applied to the output circuits 31 and 32.

In the even data test mode, an even data test pattern is generated. The even data output circuit 31 is operated by the even data output clock signals CLKDQ_EVEN and CLKDQB_EVEN, and the odd data output clock signals CLKDQ_ODD and CLKDQB_ODD are deactivated or not applied so that the odd data output circuit 32 is blocked. During the even data test mode, the output latch 33 outputs the even data DATA_EVEN only.

In the odd data test mode, an odd data test pattern is generated. The odd data output circuit 32 is operated by the odd data output clock signals CLKDQ_ODD and CLKDQB_ODD, and the even data output clock signals CLKDQ_EVEN and CLKDQB_EVEN are deactivated or not applied so that the odd data output circuit 31 is blocked. During the odd data test mode, the output latch 33 outputs the odd data DATA_ODD only.

In the normal operation mode (in other words, not in the test mode) the even and odd data output clock signals CLKDQ_EVEN, CLKDQB_EVEN, CLKDQ_ODD and CLKDQB_ODD are applied so that the even data DATA_EVEN and the odd data DATA_ODD are alternately output.

In various example embodiments, the even and odd data output clock signals CLKDQ_EVEN, CLKDQB_EVEN, CLKDQ_ODD and CLKDQB_ODD may be applied to control terminals of the transmission gates 311, 313, 321 and 323 in different ways. For example, in one embodiment, the even and the odd data output clock signals CLKDQ_EVEN, CLKDQB_EVEN, CLKDQ_ODD and CLKDQB_ODD may have the same frequency, the same duty ratio, and the same phase. In another embodiment, the even and the odd data output clock signals CLKDQ_EVEN, CLKDQB_EVEN, CLKDQ_ODD and CLKDQB_ODD may have the same frequency, the same duty ratio, and the opposite phase. When each of the data output clock signals CLKDQ_EVEN, CLKDQB_EVEN, CLKDQ_ODD and CLKDQB_ODD are connected with each of the transmission gates 311, 313, 321 and 323 as in FIG. 3, the even and odd data output clock signals CLKDQ_EVEN and CLKDQ_ODD may have the same phase.

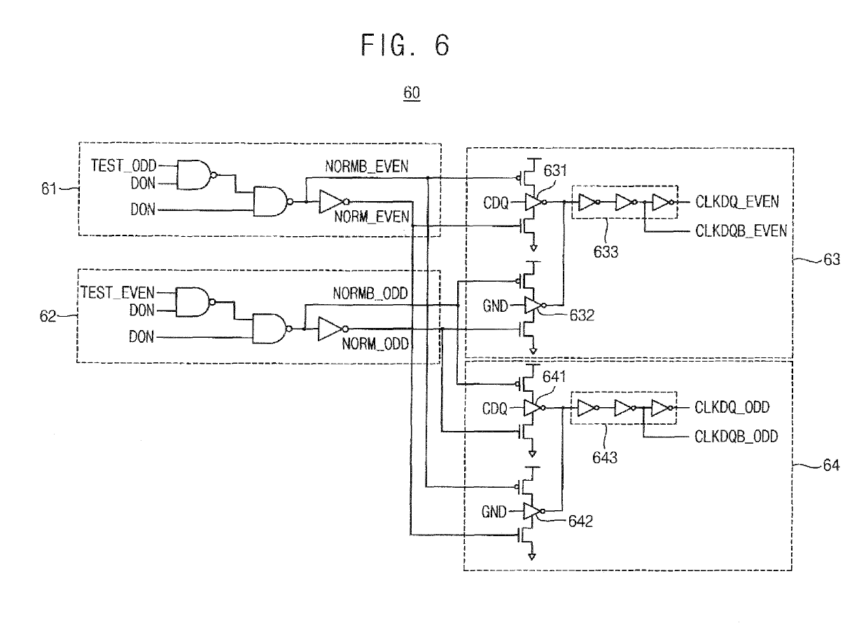

FIGS. 4 and 5 show timing diagrams including output clock signals provided to the data serializer of FIG. 3, and also show output data output from the data serializer, FIG. 4 illustrates signals in an even data test mode, and FIG. 5 illustrates signals in an odd data test mode.

Referring to FIG. 4, an even data output clock signal CLKDQ_EVEN is activated, and an odd data output clock signal CLKDQ_ODD is deactivated. Because only even data DATA_EVEN is activated in the data serializer, the even data DATA_EVEN may be output, as indicated by DATA of FIG. 4, responsive to the even data output clock signal CLKDQ_EVEN. The output even data DATA_EVEN has a valid data window that is equivalent to one cycle of an external clock signal EXT_CLK. According to this embodiment, the output data DATA may be synchronized at the edge of the external clock signal EXT_CLK using a logic circuit such as a delay-locked loop (DLL).

Referring to FIG. 5, an odd data output clock signal CLKDQ_ODD is activated, and an even data output clock signal CLKDQ_EVEN is deactivated. Because only odd data DATA_ODD is activated in the data serializer, the odd data DATA_ODD may be output, as indicated by DATA of FIG. 5, responsive to the odd data output clock signal CLKDQ_ODD. The output odd data DATA_ODD has a valid data window that is equivalent to one cycle of an external clock signal EXT_CLK. According to this embodiment, the output data DATA may be synchronized at the edge of the external clock signal EXT_CLK using a logic circuit such as a delay-locked loop (DLL).

FIG. 6 shows a circuit diagram including an output clock signal generating circuit in FIG. 3. Referring to FIG. 6, the output clock signal generating circuit 60 includes an even operation signal generating unit 61, an odd operation signal generating unit 62, an even data clock signal generating unit 63, and an odd data clock signal generating unit 64. Each of the even and odd data clock signal generating units 63 and 64 receives a data output clock signal CDQ and a ground signal GND.

The even and odd operation signal generating units 61 and 62 generate even and odd operation signals NORM_EVEN, NORMB_EVEN, NORM_ODD and NORMB_ODD, respectively. The even and odd data clock signal generating units 63 and 64 include tristate inverters 631, 632, 641 and 642 to which the data output clock signal CDQ and the ground signal GND are respectively applied. The tristate inverters 631, 632, 641 and 642 are activated or deactivated according to the even operation signals NORM_EVEN and NORMB_EVEN, and the odd operation signals NORM_ODD and NORMB_ODD.

According to one embodiment, the output clock signal generating circuit 60 may generate non-inverted data output clock signals CLKDQ_EVEN and CLKDQ_ODD, and inverted data output clock signals CLKDQB_EVEN and CLKDQB_ODD through phase splitters 633 and 643. There is a 180-degree phase difference between the non-inverted data output clock signals and the inverted data output clock signals.

The even operation signals NORM_EVEN and NORMB_EVEN are generated responsive to an odd test signal TEST_ODD and an output pin usage signal DON. The odd operation signals NORM_ODD and NORM_ODD are generated responsive to an even test signal TEST_EVEN and the output pin usage signal DON. The output pin usage signal DON may be defined as a signal of logic high when the output pin is used, and logic low when the output pin is not used.

The data output clock signal CDQ is applied to the tristate inverters 631, 632, 641 and 642 and is output as the even data clock signal CLKDQ_EVEN and the odd data clock signal CLKDQ_ODD according to the even operation signals NORM_EVEN and NORMB_EVEN, and the odd operation signals NORM_ODD and NORMB_ODD.

During an even data test mode, an even test signal TEST_EVEN is logic high and an odd test signal TEST_ODD is logic low. The even operation signal NORM_EVEN of logic high and the inverted signal NORMB_EVEN are generated in the even operation signal generating unit 61. The odd operation signal NORM_ODD of logic low and the inverted signal NORMB_ODD are generated in the odd operation signal generating unit 62.

In the even data test mode, the even data clock signal generating unit 63 is activated according to the even operation signal NORM_EVEN of logic high, and outputs the even data clock signal CLKDQ_EVEN corresponding to the data output clock signal CDQ. The 180-degree phase shifted clock signal CLKDQB_EVEN of the even data clock signal CLKDQ_EVEN may also be output. In this case, because the ground signal GND is blocked according to the odd operation signal NORM_ODD of logic low, the output even data clock signal CLKDQ_EVEN is not affected by the ground signal GND.

In the even data test mode, the odd data clock signal generating unit 64 outputs the odd data clock signal CLKDQ_ODD corresponding to the ground signal GND according to the even operation signal NORM_EVEN of logic high. The data output clock signal CDQ is blocked according to the odd operation signal NORM_ODD of logic low. Accordingly, the even data clock signal CLKDQ_EVEN is a predetermined time delayed signal of the data output clock signal CDQ, and the odd data clock signal CLKDQ_ODD maintains the level of the ground signal GND.

During an odd data test mode, the odd test signal TEST_ODD is logic high and the even test signal TEST_EVEN is logic low. The odd operation signal NORM_ODD of logic high and the inverted signal NORMB_ODD are generated in the odd operation signal generating unit 62. The even operation signal NORM_EVEN of logic low and the inverted signal NORMB_EVEN are generated in the even operation signal generating unit 61.

In the odd data test mode, the odd data clock signal generating unit 64 is activated according to the odd operation signal NORM_ODD of logic high, and outputs the odd data clock signal CLKDQ_ODD corresponding to the data output clock signal CDQ. The 180-degree phase shifted clock signal CLKDQB_ODD of the odd data clock signal CLKDQ_ODD may also be output. In this case, because the ground signal GND is blocked according to the even operation signal NORM_EVEN of logic low the output odd data clock signal CLKDQ_ODD is not affected by the ground signal GND.

In the odd data test mode, the even data clock signal generating unit 63 outputs the even data clock signal CLKDQ_EVEN corresponding to ground signal GND according to the odd operation signal NORM_ODD of logic high. The data output clock signal CDQ is blocked according to the even operation signal NORM_EVEN of logic low. Accordingly, the odd data clock signal CLKDQ_ODD is a predetermined time delayed signal of the data output clock signal CDQ, and the even data clock signal CLKDQ_EVEN maintains the level of the ground signal GND.

The even data clock signal CLKDQ_EVEN and the odd data clock signal CLKDQ_ODD may be delayed for a predetermined time compared with the data output clock signal CDQ, and a delayed-locked loop (not shown) can compensate for predetermined delay time.

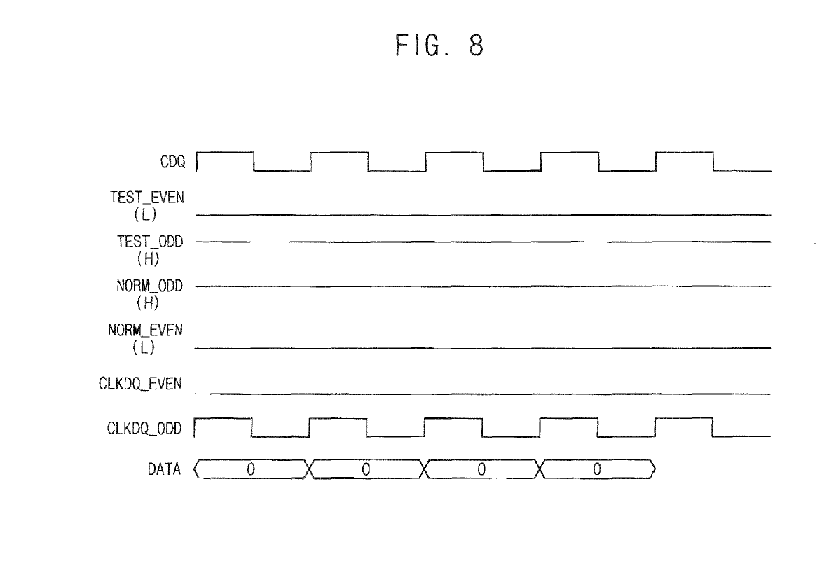

FIGS. 7 and 8 show timing diagrams including signals of a data serializer according to an example embodiment operating in an even data test mode and in an odd data test mode.

Referring to FIG. 7, when the data serializer according to an example embodiment of the present invention operates in the even data test mode, an even test signal TEST_EVEN and an even operation signal NORM_EVEN are logic high, and an odd test signal TEST_ODD and an odd operation signal NORM_ODD are logic low. The waveform of an even data clock signal CLKDQ_EVEN is identical to the waveform of a data output clock signal CDQ, during which time an odd data clock signal CLKDQ_ODD maintains logic low. Even data DATA_EVEN is output with a valid data window of one clock cycle.

Referring to FIG. 8, when the data serializer according to an example embodiment of the present invention operates in the odd data test mode, an even test signal TEST_EVEN and an even operation signal NORM_EVEN are logic low, and an odd test signal TEST_ODD and an odd operation signal NORM_ODD are logic high. An even data clock signal CLKDQ_EVEN maintains logic low, and the waveform of an odd data clock signal CLKDQ_ODD is identical to the waveform of a data output clock signal CDQ. Odd data DATA_ODD is output with a valid data window of one clock cycle.

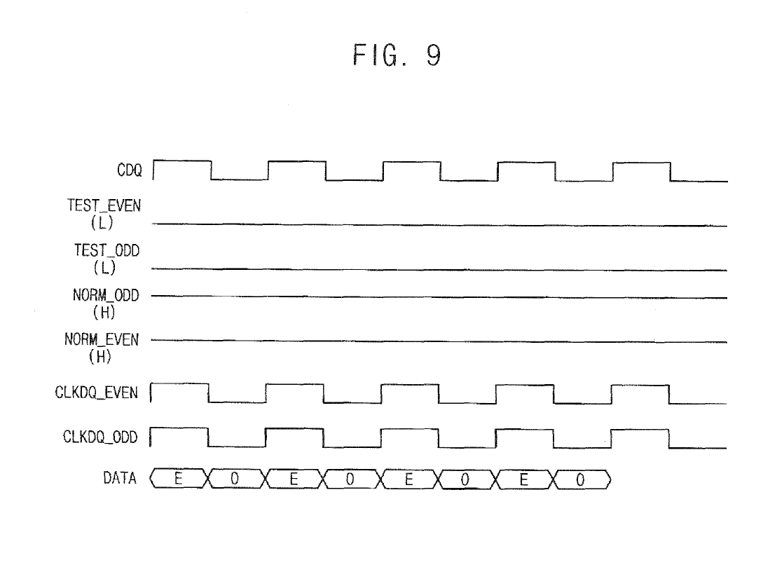

FIG. 9 is a timing diagram illustrating signals of a data serializer according to an example embodiment operating in a normal operation mode. Because even and odd test signals TEST_EVEN and TEST_ODD are logic low, even and odd operation signals NORM_EVEN and NORM_ODD become logic high. Accordingly, an even data clock signal CLKDQ_EVEN and an odd data clock signal CLKDQ_ODD may have the same phase. Output data is synchronized at the edge of an external clock signal by a DLL (not shown).

Although a data serializer receiving and serializing two data inputs in one cycle is described above, other embodiments of the present invention may be applied to a data serializer receiving and serializing four or eight data inputs in one cycle.

As described above, according to various embodiments of the present invention, a method of data serialization and a data serializer may serialize output data without loss of a valid data output time. Furthermore, in a test method according to some embodiments of the present invention, a semiconductor memory device may be tested by serializing parallel test data without a loss of the valid data output time in a high-speed data output (HSDO) test mode.

While the example embodiments of the present invention and their advantages have been described in detail, it should be understood that various changes, substitutions and alterations may be made herein without departing from the scope of the invention.

What is claimed is:

1. A method of testing a semiconductor memory, comprising:
generating test data in the semiconductor memory device;
generating a plurality of data output clock signals;
controlling a plurality of output circuits with the data output clock signals;
selectively activating one of the data output clock signals according to a test mode;
selectively deactivating another one of the data output clock signals according to the test mode;
activating one of the output circuits responsive to the activated data output clock signal; and
serializing the test data transferred through the activated output circuit.

2. The method of claim 1, wherein the test mode comprises even and odd data test modes, the plurality of data output clock signals comprises even and odd data output clock signals, and the plurality of output circuits comprises even and odd output circuits.

3. The method of claim 2, wherein generating the plurality of data output clock signals comprises:
activating the even data output clock signal and deactivating the odd data output clock signal during the even data test mode; and
activating the odd data output clock signal and deactivating the even data output clock signal during the odd data test mode.

4. The method of claim 3, wherein the even output circuit comprises first and second transmission gates and a first latch coupled serially between the first and second transmission gates, and the odd output circuit comprises third and fourth transmission gates and a second latch coupled serially between the third and fourth transmission gates, and
wherein activating one of the output circuits comprises:
alternately activating the first and second transmission gates responsive to the even data output clock signal and deactivating at least one of the third and fourth transmission gates responsive to the odd data output clock signal during the even data test mode; and
alternately activating the third and fourth transmission gates responsive to the odd data output clock signal and deactivating at least one of the first and second transmission gates responsive to the even data output clock signal during the odd data test mode.

5. The method of claim 1, wherein a single one of the data output clock signals is activated during the test mode.

6. A method of data serialization, comprising:
generating a plurality of data output clock signals;
controlling a plurality of output circuits with the data output clock signals;
selectively activating at least one of the data output clock signals according to an output mode;
applying data to at least one of the plurality of output circuits;
selectively activating the output circuits responsive to the data output clock signals and the output mode;
serializing the data transferred through the at least one activated output circuit; and
applying the serialized data to an output latch responsive to the at least one of the activated output clock signals.

7. The method of claim 6, wherein the output mode comprises even and odd data test modes, the plurality of data output clock signals comprises even and odd data output clock signals, and the plurality of output circuits comprises even and odd output circuits.

8. The method of claim 7, wherein generating the plurality of data output clock signals comprises:
activating the even data output clock signal and deactivating the odd data output clock signal during the even data test mode; and
activating the odd data output clock signal and deactivating the even data output clock signal during the odd data test mode.

9. The method of claim 8, wherein the even output circuit comprises first and second transmission gates and a first latch coupled serially between the first and second transmission gates, and the odd output circuit comprises third and fourth transmission gates and a second latch coupled serially between the third and fourth transmission gates, and
wherein activating one of the output circuits comprises:
alternately activating the first and second transmission gates responsive to the even data output clock signal and deactivating at least one of the third and fourth transmission gates responsive to the odd data output clock signal during the even data test mode; and
alternately activating the third and fourth transmission gates responsive to the odd data output clock signal and deactivating at least one of the first and second transmission gates responsive to the even data output clock signal during the odd data test mode.

10. The method of claim 6, wherein a single one of the data output clock signals is activated when the output mode is a test mode and all of the data output clock signals are activated when the output mode is a normal operation mode.

11. The method of claim 10, wherein the applied data is alternately transferred from each of the plurality of output circuits to the output latch during the normal operation mode responsive to all of the data output clock signals.

12. A data serializer comprising:
a clock circuit configured to generate a plurality of data output clock signals, each of the data output clock signals being selectively activated according to an output mode;
a plurality of output circuits configured to receive data responsive to at least one of the data output clock signals; and
an output latch coupled to the plurality of output circuits, configured to latch data on an output terminal of at least one of the plurality of output circuits responsive to the at least one of the data output clock signals.

13. The data serializer of claim 12, wherein the output mode comprises even and odd data test modes, the plurality of data output clock signals comprises even and odd data output clock signals, and the plurality of output circuits comprises even and odd output circuits.

14. The data serializer of claim 13, wherein the clock circuit is configured to activate the even data output clock signal and deactivate the odd data output clock signal during the even data test mode, and configured to activate the odd data output clock signal and deactivate the even data output clock signal during the odd data test mode.

15. The data serializer of claim 14, wherein the even output circuit comprises first and second transmission gates and a first latch coupled serially between the first and second transmission gates, and the odd output circuit comprises third and fourth transmission gates and a second latch coupled serially between the third and fourth transmission gates, and
wherein the first and second transmission gates are alternately activated responsive to the even data output clock signal and at least one of the third and fourth transmission gates is deactivated responsive to the odd data output clock signal during the even data test mode, and the third and fourth transmission gates are alternately activated responsive to the odd data output clock signal and at least one of the first and second transmission gates is deactivated responsive to the even data output clock signal during the odd data test mode.

16. The data serializer of claim 15, wherein the first latch is directly coupled to the first and second transmission gates, and the second latch is directly coupled to the third and fourth transmission gates.

17. The data serializer of claim 16, wherein the output latch is directly coupled to at least one of the first, second, third, and fourth transmission gates.

18. The data serializer of claim 12, wherein the clock circuit is configured to activate one of the data output clock signals when the output mode is a test mode and configured to activate all of the data output clock signals when the output mode is a normal operation mode.

19. The data serializer of claim 18, wherein the received data is alternately transferred from each of the plurality of output circuits to the output latch during the normal operation mode responsive to all of the data output clock signals.

20. The data serializer of claim 12, wherein each of the output circuits comprises at least one transmission gate configured to transfer the received data when the at least one of the data output clock signals is activated, and configured to intercept the received data when another at least one of the data output clock signals is deactivated.
